(19) United States
(12) Patent Application Publication
(10) Pub. No.: US 2014/0110622 A1
(43) Pub. Date: Apr. 24, 2014

(54) POLYMER MATERIAL CONTAINING ORGANICALLY MODIFIED LAYERED SILICATES

(71) Applicants: Joachim Wagner, Koln (DE); Berit Krauter, Opladen (DE); Stefanie Eiden, Leverkusen (DE); Deliani Lovera-Prieto, Niederlande (NL); Holger Egger, Koln (DE)

(72) Inventors: Werner Jenninger, Ahorn (DE); Joachim Wagner, Koln (DE); Berit Krauter, Opladen (DE); Stefanie Eiden, Leverkusen (DE); Deliani Lovera-Prieto, Niederlande (NL); Holger Egger, Koln (DE)

(73) Assignee: Bayer Intellectual Property GmbH, Monheim (DE)

(21) Appl. No.: 13/809,426

(22) PCT Filed: Jul. 11, 2011
(86) PCT No.: PCT/EP2011/061773

§ 371 Date: Oct. 7, 2013

(30) Foreign Application Priority Data
Jul. 12, 2010 (EP) 10169294.5

(51) Int. Cl. H01L 41/193

(52) U.S. Cl. CPC H01L 41/193
USPC 252/62.9 R

(57) ABSTRACT

The present invention relates to a polymer material comprising a polymer and an organically modified layered silicate dispersed in the polymer. The total content of alkali and/or alkaline earth metal cations in the polymer material is ≦1 ppm. It relates further to the use of the polymer material as an electret material, and to an electromechanical converter comprising such a polymer material.

The present invention relates to a polymer material comprising a polymer and an organically modified layered silicate dispersed in the polymer. It relates further to the use of the polymer material as an electret material, and to an electromechanical converter comprising such a polymer material.

An electret is a dielectric which carries a quasi-permanent electric charge and/or polarisation. Such electrets are widely used as acoustic membranes, for example in microphones, sensors and/or actuators.

Polymer electrets can further be used as self-adhesive, reusable films which can be removed without leaving a residue, for example in the design sector, in poster advertising or for information signs.

Polymer electrets are used in particular in electromechanical, for example piezoelectric, arrangements, such as loudspeakers, vibration converters, pyroelectric detectors and capacitors. Electromechanical or piezoelectric refers to the ability to generate an electric potential on the basis of an applied mechanical load. An electromechanical, for example piezoelectric, arrangement can be formed, inter alia, by a structure that is heterogeneous, in particular over its thickness. For example, multilayer arrangements of polymer foams and compact polymer films stacked one above the other are known, in which the polymer films serve as an electret and carry charges which, when the arrangement is subjected to mechanical stress, produce an electrical reaction.

In the electret films that are available commercially today, as are used, for example, in microphones, polytetrafluoroethylene (PTFE) or polytetrafluoroethylene-propylene copolymer (FEP) is used almost exclusively as the electret material. The advantage of these fluorinated polymers is that they have a good charge storage behaviour. However, these polymers are very expensive and, especially in the case of polytetrafluoroethylene, are difficult to process.

Attempts have therefore been made, by adding additives to a polymer material that is more suitable from an economic and technical point of view, to improve its electret properties. Organic chemical additives for improving the electret behaviour of polycarbonates are described, for example, in EP 2 159 222 A1. A disadvantage of those additives is that they have to be synthesised specially.

Layered silicates are an important subgroup of the silicate minerals. They are distinguished by a very high degree of variability and can consequently be used for many different applications.

In layered silicates, SiO₄ tetrahedrons are crosslinked to form layers having the composition Si₂O₅. These tetrahedral layers alternate with so-called octahedral layers, in which a cation, especially aluminium and magnesium, is surrounded octahedrally by hydroxide or oxygen. A distinction is made between two-layer minerals, such as, for example, kaolinite or serpentine, and three-layer minerals, especially montmorillonite or mica. In two-layer phyllosilicates, a tetrahedral layer is in each case bonded to an octahedral layer; in three-layer phyllosilicates, an octahedral layer is bonded to two tetrahedral layers.

For that reason, two-dimensional layers form which are held together by electrostatic interaction. The actual layers are themselves in most cases partially negatively charged and the charges are balanced by cations in the interlayer spaces. Most of these compounds can therefore readily be swollen and dispersed in water. This process is called exfoliation. By this process, particles referred to as “nanolayers” are produced. Depending on the structure of the layered silicates, the aspect ratio of the nanolayers can vary considerably.

The counter-ions in the intermediate layers (mostly sodium ions) can be exchanged, so that the possibility exists of modifying the layers with a very wide variety of cationic compounds. In order to render the layered silicates compatible also with non-aqueous media, for example for polycarbonate, a wide choice of suitable modifiers are available. Common organic modifiers are trimethylalkylammonium compounds, which preferentially adsorb at the surface of the layered silicates and accordingly render the layered silicates hydrophobic. Further suitable modifiers are non-ionic surfactants, anionic surfactants and cationic surfactants as well as block copolymers or polyelectrolytes. In the presence of low molecular weight surfactants having molecular weights of less than 1000 g/mol, cosurfactants, for example alkanols having C₁-C₁₀-carbon chains, may be required.

An organic modification of the layered silicates is generally carried out by completely dispersing the layered silicate in aqueous solution. The organic modifier is then added, which preferentially adsorbs at the layered silicate surface, until all the charges are balanced. The suspension can subsequently be purified, dried and processed further as a solid. Purification is carried out in particular in order to remove the intermediate-layer ions of the layered silicates and optionally the counter-ions of the organic modifiers, which would otherwise remain in the dried material.

In respect of modified clay materials, EP 0 952 187 A1 discloses, for example, a composition of clay and an organic chemical compound comprising an ion-exchanged reaction product which is obtainable from the reaction of a smectite clay, a quaternary ammonium compound and a non-anionic organic material. The patent application further discloses a nanocomposite comprising a matrix from the group polymer, plastic and resin as well as an above-described composition of clay and an organic chemical compound. The hybrid organoclay consists of an organic chemical/phyllosilicate clay intercalate which has been ion-exchanged with quaternary ammonium compounds. Because the hybrid organoclay is hydrophobic, it can be washed with water in order to remove reaction salts and excess water-soluble or water-dispersible polymers. A clean product can be obtained by inexpensive measures such as filtration. In this manner, energy-intensive methods of removing water would be avoided. A field of application of such a clay is as a rheological additive.

However, there is no mention of the electret properties of the nanocomposite. Furthermore, that patent application does not deal with the question of whether the polymer material has lower stability owing to cationic impurities.

Accordingly, the object of the present invention is to provide alternative polymer materials which are suitable as electrets and are easy to process.

The object is achieved according to the invention by a polymer material comprising a polymer and an organically modified layered silicate dispersed in the polymer, the polymer material being distinguished by the fact that the total content of alkali and/or alkaline earth metal cations in the polymer material is ≦1 ppm.

The content of the mentioned cations can preferably be determined by means of atom absorption spectroscopy (AAS). Such low contents of sodium ions in particular lead to a markedly reduced or prevented chain degradation of sensitive polymers in which the monomers are linked with one another via hydrolysable bonds. Polycarbonate in particular comes into consideration here.

In that manner it is possible, for example, to produce filler-containing polymer electret films by the extrusion or calendering process without having to consider the possibility of polymer chain degradation at the conventional processing temperatures.

As compared with a polymer without addition of the organically modified layered silicates, the polymer material according to the invention exhibits a smaller drop in the surface potential after charging. After corona charging at a voltage of 500 V, for example, the fall in the potential as compared with the original potential Ψ/Ψ₀ after tempering at 120° C. for 24 hours can be in a range from ≧30% to ≦50%.

The polymer material according to the invention can be prepared by a process which comprises the step of bringing a dispersion of the layered silicate into contact with an organic compound, wherein the total charge of the organic compound is preferably at least singly positive and wherein, further, contacting is carried out in the presence of an ion-exchanger resin.

In that manner, the content of free cations which have been displaced from the layered silicate by the preferably positively charged organic compound can be significantly reduced. This saves more expensive washing and cleaning steps.

The polymer serves as the matrix in which the layered silicate is dispersed. Preferably, it is a homogeneous dispersion. Suitable polymers are, for example, polyolefins, polyurethanes, polyesters, polyethers and/or polycarbonates.

Within the context of the present invention, the expression “organically modified layered silicate” denotes a layered silicate to which organic compounds are bonded. Preferably, the organic compounds are bonded to the layered silicate by means of ionic interactions.

Suitable layered silicates are in particular the above-mentioned two-layer and/or three-layer phyllosilicates. They may previously have been modified prior to the modification described in the present invention in order, for example, to render them more swellable. However, it is preferred, inter alia for cost reasons, to use unmodified layered silicates.

In the modification of the layered silicates, they are used in the form of a dispersion. The dispersing agent should thereby be capable of dissolving the positively charged organic modifier and the cations displaced from the layered silicate.

Preferably, the dispersion of the layered silicate is carried out in a dispersing agent which comprises water and/or an ionic liquid. In particular, the ionic liquids are those which are liquid at room temperature and in which the cation is organic. This can then also be used for the modification of the layered silicates. The use of water is likewise advantageous because water can be purified by distillation and/or membrane separation processes and then fed back into the process again.

The layered silicate is preferably brought into contact with an organic compound whose total charge is at least singly positive. This is to be understood as meaning the total charge of in each case one molecule of the organic compound.

Suitable organic compounds are inter alia those organic molecules having at least one single positive charge in which the positive charge is brought about by at least one quaternary ammonium group or by protonation of a primary, secondary or tertiary amino group.

However, further suitable organic compounds are inter alia polymers, particularly preferably block copolymers which, according to Foerster and Antonietti (Foerster, S. & Antonietti, M., Advanced Materials, 10, no. 3, (1998) 195), carry a solvate block for interaction with the solvent and a functional block for interaction with the particle surface. Such interactions can in particular be interactions of the ligand, acid-base, electrostatic and/or complex, low-energy type.

As has already been stated, the total charge of the molecule of the organic compound should preferably be at least singly positive. This can be achieved in particular by protonation or alkylation of suitable groups in the functional block of the molecule.

The organic compounds preferably have molar masses of from ≧400 g/mol to ≦20,000 g/mol and more preferably from ≧1000 g/mol to ≦10,000 g/mol (molar masses according to DIN 53240 OH number determination).

Within the context of the modification of the silicates, contacting is further carried out in the presence of an ion-exchanger resin. The cations displaced from the layered silicate are bonded by this ion-exchanger resin and exchanged for H⁺ ions. The resin can subsequently be filtered off. In that manner, purification of the dispersion can be carried out in a very simple manner. Preferably, the ion-exchanger resin comprises basic and acidic ion-exchanger resin. Anions resulting from a protonation of functional groups of the organic compound can then also be bonded and separated off. There may be mentioned as an example chloride ions when an aminic organic compound is protonated with hydrochloric acid. The purification step can be monitored by means of conductivity measurements in the dispersion.

The invention is described hereinbelow in connection with preferred embodiments which can be combined with one another as desired, as long as the opposite clearly does not ensue. It should further be noted that, within the context of the present invention, the terms “a”, “an”, etc. are not to be understood as being numerals, as long as the opposite clearly does not ensue from the context.

In an embodiment of the polymer material according to the invention, the organically modified layered silicate comprises a layered silicate to which there are bonded compounds selected from the group comprising:

alkylammonium compounds of the general formula (NR¹R²R³R⁴)⁺, wherein R¹, R², R³ and R⁴ each independently of the others can denote:
C₁-C₁₈ alkyl, C₆-C₁₂-aryl, C₂-C₁₈-alkyl interrupted by one or more oxygen atoms, C₅-C₁₂-cycloalkyl, C₁-C₁₈-alkylcarbonyl, C₁-C₁₈-alkyloxycarbonyl, C₅-C₁₂-cycloalkylcarbonyl, C₆-C₁₂-arylcarbonyl,
wherein the mentioned radicals can each be substituted by functional groups, aryl, alkyl, aryloxy, alkyloxy, halogen, heteroatoms and/or heterocycles and/or can carry 1, 2, 3 or 4 double bonds, and
wherein R¹, R², R³ and R⁴ can denote hydrogen as long as at least one of those radicals has the meaning described above;
   block copolymers comprising a solvate block and a functional block,
wherein the solvate block is selected from the group comprising poly(styrenesulfonic acid), poly(N-alkylvinylpyridinium halide), poly(methacrylic acid), poly(methacrylates), poly(N-vinylpyrrolidone), poly(hydroxyethyl methacrylate), poly(vinyl ether), poly(ethylene oxide), poly(propylene oxide), poly(vinyl methyl ether), poly(vinyl butyl ether), polystyrene, poly(ethylenepropylene), poly(ethylethylene), poly(isobutylene), poly(dimethylsiloxane) and/or partially fluorinated blocks (PF); and
wherein the functional block is selected from the group comprising poly(N-alkylvinylpyridinium halide), poly(dimethylsiloxane), partially fluorinated blocks (PF), poly(ethylene oxide), blocks containing ligands, blocks containing mercapto groups, poly(methacrylic acid), poly(styrenesulfonic acid), poly(cyclopentadienylmethylnorbornene), poly(amino acid) blocks, PEO-PPO-PEO or PPO-PEO-PPO block copolymers, copolymers with poly(ethylene oxide)-poly(methyl methacrylate) or poly(ethylene oxide)-poly(n-butyl acrylate) blocks, amine derivatives and/or polyoxyalkyleneamines.

Within the scope of this invention, the term “alkyl” denotes acyclic saturated or unsaturated aliphatic hydrocarbon radicals which in each case can be branched or unbranched as well as unsubstituted or mono- or poly-substituted. Alkyl is preferably selected from the group comprising methyl, ethyl, n-propyl, 2-propyl, n-butyl, isobutyl, sec-butyl, tert-butyl, n-pentyl, isopentyl, neopentyl, n-hexyl, n-heptyl, n-octyl, n-nonyl, n-decyl and higher homologues up to n-octadecyl.

Within the scope of this invention, the term “aryl” denotes aromatic hydrocarbons having up to ≦12 ring members, in particular phenyls and naphthyls. Each aryl radical can be unsubstituted or mono- or poly-substituted, it being possible for the aryl substituents to be the same or different and to be in any desired and possible position of the aryl. Aryl is preferably selected from the group containing phenyl, 1-naphthyl and 2-naphthyl, each of which can be unsubstituted or mono- or poly-substituted. A particularly preferred aryl is phenyl, unsubstituted or mono- or poly-substituted.

“Halogens” are in particular F, Cl, Br and I. “Heteroatoms” are in particular N, P, O and S.

The term “heterocycles” comprises on the one hand aliphatic saturated or unsaturated (but not aromatic) cycloalkyls having in particular from three to ten ring members, in which at least one, optionally also two or three, carbon atoms have been replaced by a heteroatom or a heteroatom group in each case selected independently of one another from the group consisting of O, S, S(═O)₂, N, NH and N(C₁₋₈-alkyl), preferably N(CH₃), wherein the ring members can be unsubstituted or mono- or poly-substituted.

Also included in the term “heterocycles” are heteroaromatic compounds. This represents a 5- or 6-membered cyclic aromatic radical which contains at least 1, optionally also 2, 3, 4 or 5, heteroatoms, wherein the heteroatoms are in each case selected independently of one another from the group S, N and O and the heteroaryl radical can be unsubstituted or mono- or poly-substituted; in the case of substitution on the heteroaryl, the substituents can be the same or different and can be in any desired and possible position of the heteroaryl.

Advantageously, the alkylammonium compounds of the general formula (NR¹R²,R³,R⁴)⁺ are protonated ammonium alkoxylates of the general formula (I) and/or (II):

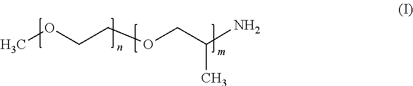

having a ratio of propylene oxide units to ethylene oxide units, indicated by the coefficients m and n, of from ≧1:20 to ≦20:1;

(R)((CH₂CH₂O)ₓ)H)((CH₂CH₂O)_{y})H)N (II)

wherein R represents a C₁₀-C₂₀-alkyl radical and the sum x+y is in a range from ≧2 to ≦30.

The ratio of propylene oxide units to ethylene oxide units, indicated by the coefficients in and n, in the general formula (I) can preferably be from ≧4:1 to ≦6:1. The number-average molecular mass is preferably in a range from ≧500 g/mol to ≦5000 g/mol and more preferably from ≧1800 g/mol to ≦2200 g/mol. Compounds of this type are available commercially under the trade name Jeffamine®.

In the general formula (II), the C₁₀-C₂₀-alkyl radical R can be, for example, cocyl, oleyl or stearyl. Preferably, the sum x+y is in a range of preferably from ≧10 to ≦25. Compounds of this type are available commercially under the trade name Genamine®.

In a further embodiment of the polymer material according to the invention, the total content of alkali and/or alkaline earth metal cations in the polymer material is from ≧0.1 ppm to ≦0.5 ppm. Preferably, the total content is from ≧0.2 ppm to ≦0.4 ppm.

In a further embodiment of the polymer material according to the invention, the polymer comprises polycarbonate. This type of polymer is particularly sensitive to impurities. Polycarbonate reacts to impurities from additives in the form of ions by a degradation of the polymer chain length, which generally also manifests itself by clouding and/or a yellowish-brownish colouration of the polymer.

In a further embodiment of the polymer material according to the invention, the layered silicate is selected from the group comprising serpentine, kaolin, talc, pyrophyllite, smectite, vermiculite, illite, mica and/or brittle mica. Smectites are preferred. The smectites also include the montmorillonites, which are particularly preferred layered silicates within the context of the present invention.

In a further embodiment of the polymer material according to the invention, the proportion of modified layered silicate in the polymer is from ≧0.005 wt. % to ≦5 wt. %. Preferably, the proportion is from ≧0.007 wt. % to ≦1 wt. % or from ≧0.01 wt. % to ≦0.1 wt. %. The proportion by weight of the polymer is calculated to include any added additives, fillers and the like.

The present invention further provides the use of a polymer material according to the invention as an electret material. This electret material can be used in an electromechanical, for example piezoelectric, arrangement. Preferably, the electret material is used in a sensor, actuator and/or generator. In particular, it can be used in a microphone or loudspeaker, for example as an acoustic membrane, in a vibration converter, in a pyroelectric detector or in a capacitor.

Such an electret element can be produced, for example, by compression moulding, especially melt compression moulding, application by doctor blade, in particular solution application by doctor blade, spread coating, spin coating, spraying, extrusion, in particular film extrusion, blow moulding, in particular film blow moulding, and/or calendering.

Charging of the electret element can be carried out by tribocharging, electron beam bombardment, cooling of the polymer melt in the electric field, application of an electric voltage or corona discharge.

The present invention likewise provides an electromechanical converter comprising a polymer material according to the invention. Such electromechanical converters are preferably sensors, actuators and/or generators, in particular in a microphone or loudspeaker, for example as an acoustic membrane, in a vibration converter or in a pyroelectric detector.

The invention is explained further by means of the following examples and the FIGURE, but without being limited thereto.

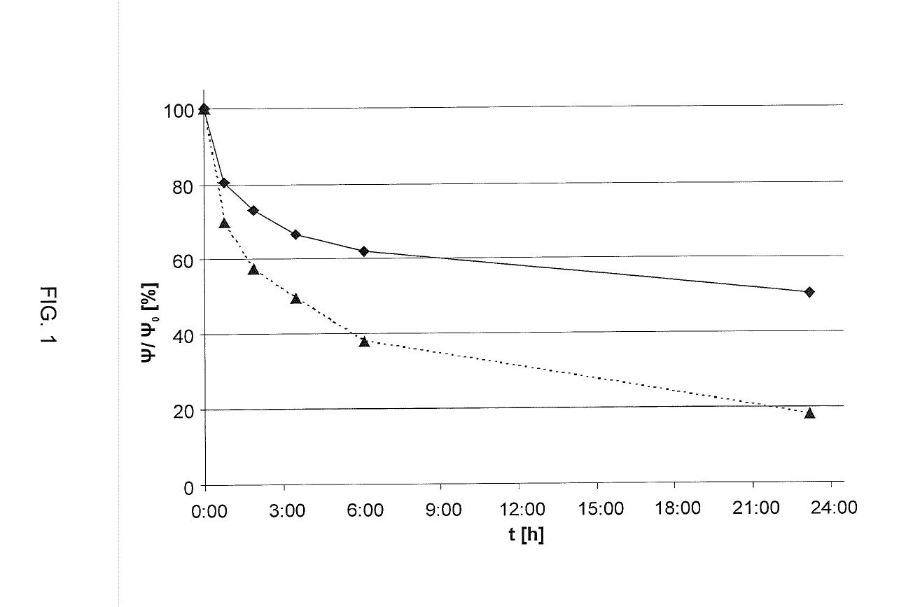

FIG. 1 shows the change over time in the fall in the surface potential for a modified and an unmodified polycarbonate material.

### EXAMPLE 1

### Preparation of an Organically Modified Layered Silicate with Jeffamine® M2005

Jeffamine® M2005 (Huntsman) is a polyetheramine of the formula:

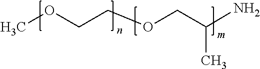

having a molar ratio of propylene oxide units to ethylene oxide units of 29:6 and a molecular mass M_{w} of 2000 g/mol.

3 kg of a 5% dispersion of natural, unmodified layered silicate (Polymer Grade Montmorillonite PGV, article number 105934, Nordmann, Rassmann GmbH) in distilled water were shaken overnight in a shaking bath.

340.2 g of Jeffamine® M2005 in 700 ml of distilled water, which had been adjusted, with stirring, to a pH value of 2 using concentrated hydrochloric acid, were placed in a three-necked flask and heated to 80° C. by means of a water bath.

The layered silicate suspension was added dropwise. During the addition, the pH value was monitored and, if required, adjusted with concentrated hydrochloric acid so that the pH value was about 3. The mixture was stirred further for three hours at 80° C. Then the mixture was slowly cooled to room temperature, with stirring.

The dispersion so obtained was filtered off with suction and separated into a solids fraction and a liquid fraction, and the moist solids fraction was taken up in fresh distilled water again. The conductivity of the suspension thereby fell from about 4 mS/cm to about 1 mS/cm.

An ion-exchanger resin (Lewatit® UltraPure 1294 MD, Lanxess; 1:1 mixture of a basic anion-exchanger resin and an acidic cation-exchanger resin) was added, with stirring, to the newly dispersed solids fraction (using only resin that is retained on a 500 μm sieve), while the conductivity of the dispersion was monitored.

The addition was stopped when the conductivity had fallen to a value of <20 μS/cm. Finally, the ion exchanger was separated off using a 400 μm sieve.

The modified layered silicate was separated from the dispersion by filtration by means of a suction filter. The moist layered silicate is redispersed with a small amount of water, added dropwise to liquid nitrogen and then freeze-dried.

### EXAMPLE 2

### Preparation of an Organically Modified Layered Silicate with Genamine® S 080

Genamine® S 080 (Clariant) is a stearyl aminoethoxylate of the formula (R)((CH₂CH₂O)ₓ)H)((CH₂CH₂O)_{y})H)N wherein x+y=8 and R=stearyl.

3 kg of a 5% dispersion of natural, unmodified layered silicate (Polymer Grade Montmorillonite PGV, article number 105934, Nordmann, Rassmann GmbH) in distilled water were shaken overnight in a shaking bath.

107.5 g of Genamine® S080 in 700 ml of distilled water, which had been adjusted, with stirring, to a pH value of 2 using concentrated hydrochloric acid, were placed in a three-necked flask and heated to ≦80° C. by means of a water bath.

The layered silicate suspension was added dropwise. During the addition, the pH value was monitored and, if required, adjusted with concentrated hydrochloric acid so that the pH value was about 3, The mixture was stirred further for three hours at 80° C. Then the mixture was slowly cooled to room temperature, with stirring.

The dispersion so obtained was filtered off with suction and separated into a solids fraction and a liquid fraction, and the moist solids fraction was taken up in fresh distilled water again. The conductivity of the suspension thereby fell from about 4 mS/cm to about 1 mS/cm.

An ion-exchanger resin (Lewatit® UltraPure 1294 MD, Lanxess; 1:1 mixture of a basic anion-exchanger resin and an acidic cation-exchanger resin) was added, with stirring, to the newly dispersed solids fraction (using only resin that is retained on a 500 μm sieve), while the conductivity of the dispersion was monitored.

The addition was stopped when the conductivity had fallen to a value of <20 μS/cm. Finally, the ion exchanger was separated off using a 400 μm sieve.

The modified layered silicate was separated from the dispersion by filtration by means of a suction filter. The moist layered silicate is redispersed with a small amount of water, added dropwise to liquid nitrogen and then freeze-dried.

### EXAMPLE 3

### Drying and Incorporation of the Modified Layered Silicates into a Polymer

The modified layered silicate from Example 2 was dried and then extruded together with a polycarbonate (Makrolon® 1140, Bayer MaterialScience AG) so that the concentration of modified layered silicate in the polymer was 1 wt. %.

The resulting material was then checked by means of viscosity measurements in respect of the molar mass degradation, which is a suitable indicator of the compatibility and purity of the layered silicate material with the polymer. If the layered silicate material contained a high proportion of impurities, in particular in the form of sodium ions, the molar mass of the polymer (here polycarbonate, which reacts particularly sensitively in this respect) would fall significantly as compared with its original value after incorporation of the layered silicate material.

A measuring method for determining the change in the molar mass of polycarbonate is measurement of the dynamic viscosity before and after treatment of the polycarbonate. In this method, the flow times of a dissolved polymer through an Ubbelohde viscometer are measured, and the difference in viscosity between the polymer solution and its solvent is then determined. Taking into account the mass concentration of the polymer solution, the viscosity number can be calculated therefrom. The viscosity number can be correlated with the molar mass of a polymer.

A relative viscosity of 1.312 was found, as compared with 1.320 for the pure polycarbonate.

Accordingly, the incorporation of the pure layered silicate material so produced did not have a significant adverse effect on the molar mass of the polycarbonate.

### EXAMPLE 4

### Increase in the Charge Storage Capacity of Polycarbonate by Modified Layered Silicate Additives

The modified layered silicate from Example 2 was dried and then compounded in a kneader, together with a polycarbonate (Makrolon® 3108, Bayer MaterialScience AG), so that the concentration of modified layered silicate in the polymer was 0.01 wt. %. The resulting granules were extruded in a single-screw extruder into films having a thickness of 100 μm.

The films were charged by means of corona discharge at a voltage of 500 V. The isothermal surface charge drop was then determined over a period of 24 hours at a temperature of 120° C. The results are shown in FIG. 1. In the FIGURE, the top curve (continuous line) shows the drop in the surface potential Ψ over time starting from an original surface potential Ψ₀ for the polycarbonate modified in this example. The bottom curve (broken line) shows, for comparison purposes, the curve for the unmodified polycarbonate.

It was found that the charge storage capacity of the polycarbonate could be improved by adding the modified layered silicates. While only 18% of the original surface potential remained in the unmodified polycarbonate after 24 hours at 120° C., that value was 50% for the polymer with the additives.

### EXAMPLE 5

### Increase in the Charge Storage Capacity of Polycarbonate by Modified Layered Silicate Additives

A procedure analogous to Example 4 was followed, except that the modified layered silicate from Example 1 was used. In two experiments, contents of the modified layered silicate in the polycarbonate of 0.03 wt. % and 0.06 wt. % were established. After tempering at 120° C. for 24 hours, a surface potential of 36% of the starting value was observed in both cases.

1-12. (canceled)

13. A polymer material comprising a polymer and an organically modified layered silicate dispersed in the polymer, wherein the total content of alkali and/or alkaline earth metal cations in the polymer material is ≦1 ppm.

14. The polymer material according to claim 13, wherein the organically modified layered silicate comprises a layered silicate to which there are bonded compounds wherein the bonded compounds are:
(a) alkylammonium compounds of the general formula (NR¹R²R³R⁴)⁺, wherein R¹, R², R³ and R⁴ each independently of the others can denote:
C₁-C₁₈-alkyl, C₆-C₁₂-aryl, C₂-C₁₈-alkyl interrupted by one or more oxygen atoms, C₅-C₁₂-cycloalkyl, C₁-C₁₈-alkylcarbonyl, C₁-C₁₈-alkyloxycarbonyl, C₅-C₁₂-cycloalkylcarbonyl, or C₆-C₁₂-arylcarbonyl,
wherein the mentioned radicals can each be substituted by functional groups, aryl, alkyl, aryloxy, alkyloxy, halogen, heteroatoms and/or heterocycles and/or can carry 1, 2, 3 or 4 double bonds, and
wherein R¹, R², R³ and R⁴ can denote hydrogen as long as at least one of those radicals has the meaning described above;
(b) block copolymers comprising a solvate block and a functional block,
wherein the solvate block is poly(styrenesulfonic acid), poly(N-alkylvinylpyridinium halide), poly(methacrylic acid), poly(methacrylates), poly(N-vinylpyrrolidone), poly(hydroxyethyl methacrylate), poly(vinyl ether), poly(ethylene oxide), poly(propylene oxide), poly(vinyl methyl ether), poly(vinyl butyl ether), polystyrene, poly(ethylenepropylene), poly(ethylethylene), poly(isobutylene), poly(dimethylsiloxane) or partially fluorinated blocks (PF) or a mixture thereof; and
wherein the functional block is poly(N-alkylvinylpyridinium halide), poly(dimethylsiloxane), partially fluorinated blocks (PF), poly(ethylene oxide), blocks containing ligands, blocks containing mercapto groups, poly(methacrylic acid), poly(styrenesulfonic acid), poly(cyclopentadienylmethylnorbornene), poly(amino acid) blocks, PEO-PPO-PEO or PPO-PEO-PPO block copolymers, copolymers with poly(ethylene oxide)-poly(methyl methacrylate) or poly(ethylene oxide)-poly(n-butyl acrylate) blocks, amine derivatives or polyoxyalkyleneamines or a mixture thereof.

15. The polymer material according to claim 14, wherein the alkylammonium compounds of the general formula (NR¹R²,R³,R⁴)⁺ are protonated ammonium alkoxylates of the general formula (I) and/or (II): 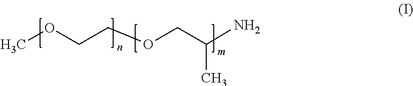
having a ratio of propylene oxide units to ethylene oxide units, indicated by the coefficients m and n, of from ≧1:20 to ≦20:1;
(R)((CH₂CH₂O)ₓ)H)((CH₂CH₂O)_{y})H)N (II)
wherein R represents a C₁₀-C₂₀-alkyl radical and the sum x+y is in a range from ≧2 to ≦30.

16. The polymer material according to claim 13, wherein the total content of alkali and/or alkaline earth metal cations in the polymer material is from ≧0.1 ppm to ≦0.5 ppm.

17. The polymer material according to claim 13, wherein the polymer comprises polycarbonate.

18. The polymer material according to claim 13, wherein the layered silicate is serpentine, kaolin, talc, pyrophyllite, smectite, vermiculite, illite, mica or brittle mica or a mixture thereof.

19. The polymer material according to claim 13, wherein the organically modified layered silicate comprises a layered silicate modified with ammonium alkoxylate.

20. The polymer material according to claim 13, wherein the proportion of modified layered silicate in the polymer is from ≧0.005 weight % to ≦5 weight %.

21. An electret material which comprises the polymer material according to claim 13.

22. A sensor, an actuator or a generator which comprises the electret material according to claim 21.

23. An electromechanical converter comprising the polymer material according to claim 13.

24. The electromechanical converter according to claim 23, wherein the converter is a sensor, an actuator or a generator.
